(19) United States
(12) Patent Application Publication
(10) Pub. No.: US 2025/0031386 A1
(43) Pub. Date: Jan. 23, 2025

(54) THERMAL DISSIPATION IN STACKED MEMORY DEVICES AND ASSOCIATED SYSTEMS AND METHODS

(71) Applicant: Micron Technology, Inc., Boise, ID (US)

(72) Inventors: Lingming Yang, Meridian, ID (US); Raghukiran Sreeramaneni, Frisco, TX (US); Nevil N. Gajera, Meridian, ID (US)

(21) Appl. No.: 18/777,870

(22) Filed: Jul. 19, 2024

Related U.S. Application Data
(60) Provisional application No. 63/528,074, filed on Jul. 20, 2023.

(51) Int. Cl. H10B 80/00; H01L 25/065; H01L 25/18

(52) U.S. Cl. CPC H10B 80/00; H01L 25/0657; H01L 25/18; H01L 2225/06513; H01L 2225/06541; H01L 2225/06589

(57) ABSTRACT

High-bandwidth memory (HBM) devices and associated systems and methods are disclosed herein. In some embodiments, the HBM devices include a first die, a plurality of second dies carried by a signal routing region of the first die, and active through substrate vias (TSVs) positioned within a footprint of the signal routing region. The active TSVs extend from a first metallization layer in the first die to a second metallization layer in an uppermost memory die. The HBM devices also include a cooling network configured to transport heat away from the first die. For example, the cooling network can include a thermally conductive layer carried by a thermal region of the first die and cooling TSVs in contact with the thermally conductive layer. The thermally conductive TSVs extend from the thermally conductive layer to an elevation at or above a top surface of the uppermost memory die.

### CROSS-REFERENCE TO RELATED APPLICATION(S)

The present application claims priority to U.S. Provisional Patent Application No. 63/528,074, filed Jul. 20, 2023, the disclosure of which is incorporated herein by reference in its entirety.

### TECHNICAL FIELD

The present technology is generally related to vertically stacked semiconductor devices and more specifically to systems and methods for thermal dissipation in stacked semiconductor devices.

### BACKGROUND

Microelectronic devices, such as memory devices, microprocessors, and other electronics, typically include one or more semiconductor dies mounted to a substrate and encased in a protective covering. The semiconductor dies include functional features, such as memory cells, processor circuits, imager devices, interconnecting circuitry, etc. To meet continual demands on decreasing size, wafers, individual semiconductor dies, and/or active components are typically manufactured in bulk, singulated, and then stacked on an interposer and/or a support substrate (e.g., a printed circuit board (PCB) or other suitable substrates). The stacked dies can then be coupled to the interposer and/or the support substrate (sometimes also referred to as a package substrate) through bond wires in shingle-stacked dies (e.g., dies stacked with an offset for each die) and/or through substrate vias (TSVs) between the dies and the support substrate.

### BRIEF DESCRIPTION OF THE DRAWINGS

FIG. 1 is a schematic diagram illustrating an environment that incorporates a high-bandwidth memory architecture.

FIG. 2 is a partially schematic cross-sectional diagram of a system-in-package device configured in accordance with some embodiments of the present technology.

FIG. 3 is a partially schematic cross-sectional diagram of portion of a high-bandwidth memory device configured in accordance with some embodiments of the present technology.

FIG. 4 is a partially schematic cross-sectional diagram of a system-in-package device configured in accordance with further embodiments of the present technology.

FIGS. 5A and 5B are partially schematic top views of an interface die and an uppermost memory die from a high-bandwidth memory device, respectively, configured in accordance with some embodiments of the present technology.

FIG. 6 is a partially schematic cross-sectional diagram of a system-in-package device configured in accordance with further embodiments of the present technology.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

High data reliability, high speed of memory access, lower power consumption, and reduced chip size are features that are demanded from semiconductor memory. In recent years, three-dimensional (3D) memory devices have been introduced. Some 3D memory devices are formed by stacking memory dies vertically, and interconnecting the dies using through-silicon (or through-substrate) vias (TSVs). Benefits of the 3D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 3D memory devices contribute to higher memory access speed, lower power consumption, and chip size reduction. Example 3D memory devices include Hybrid Memory Cube (HMC) and High Bandwidth Memory (HBM). For example, HBM is a type of memory that includes a vertical stack of dynamic random-access memory (DRAM) dies and an interface die (which, e.g., provides the interface between the DRAM dies of the HBM device and a host device).

In a system-in-package (SiP) configuration, HBM devices may be integrated with a host device (e.g., a graphics processing unit (GPU) and/or computer processing unit (CPU)) using a base substrate (e.g., a silicon interposer, a substrate of organic material, a substrate of inorganic material and/or any other suitable material that provides interconnection between GPU/CPU and the HBM device and/or provides mechanical support for the components of an SiP device), through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device, and the silicon interposer integrating HBM devices and a host device, enable the routing of a greater number of signals (e.g., wider data buses) than is typically found between packaged memory devices and a host device (e.g., through a printed circuit board (PCB)). The high-bandwidth interface within a SiP enables large amounts of data to move quickly between the host device (e.g., GPU/CPU) and HBM devices during operation. For example, the high-bandwidth channels can be on the order of 1000 gigabytes per second (GB/s, sometimes also referred to as gigabits (Gb)). It will be appreciated that such high-bandwidth data transfer between a GPU/CPU and the memory of HBM devices can be advantageous in various high-performance computing applications, such as video rendering, high-resolution graphics applications, artificial intelligence and/or machine learning (AI/ML) computing systems and other complex computational systems, and/or various other computing applications.

However, HBM devices can present certain challenges. One such challenge is that the vertically-stacked arrangement of HBM devices can make it difficult to dissipate heat from components of the HBM devices (e.g., DRAM dies and/or interface dies). For example, the interface die of an HBM device typically has the highest power density of the devices within the HBM device (due to the speed at which it operates), but is often arranged at the bottom of the HBM device and furthest from conventional cooling media. As a result, there exists a risk that the interface dic may suffer from inadequate cooling. Accordingly, described herein are systems and associated methods that improve thermal dissipation within vertically-stacked memory devices, such as HBM devices.

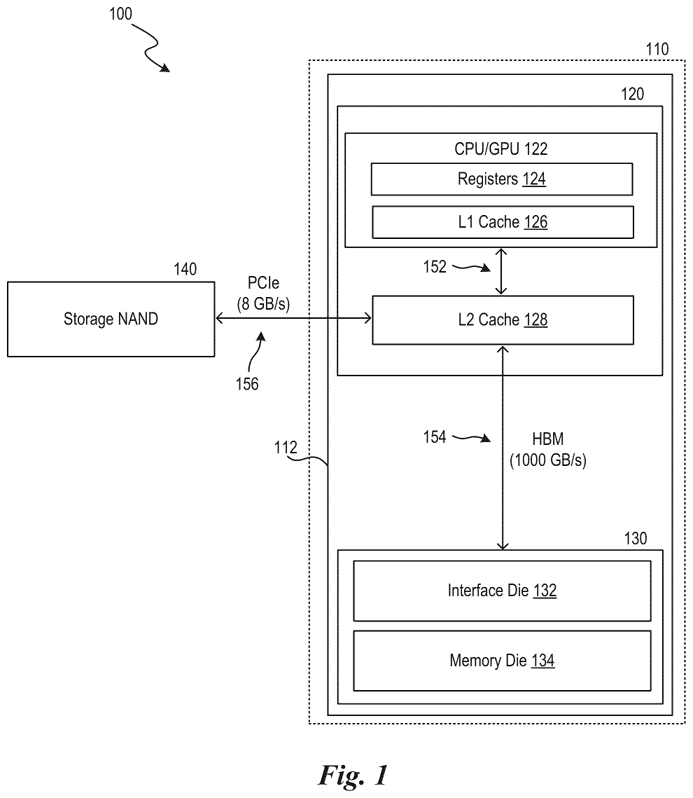

FIG. 1 is a schematic diagram illustrating an environment 100 that incorporates a high bandwidth memory architecture. As illustrated in FIG. 1, the environment 100 includes a SiP device 110 having one or more processing devices 120 (one illustrated in FIG. 1, sometimes also referred to herein as one or more “hosts”), and one or more HBM devices 130 (one illustrated in FIG. 1), integrated with a silicon interposer 112 (or any other suitable base substrate). The environment 100 additionally includes a storage device 140 coupled to the SiP device 110. The processing devices(s) 120 can include one or more CPUs and/or one or more GPUs, referred to as a processing unit 122, each of which may include registers 124 and a first level of cache 126. The first level of cache 126 (also referred to herein as “L1 cache”) is communicatively coupled to a second level of cache 128 (also referred to herein as “L2 cache”) via a first communication path 152. In the illustrated embodiment, the L2 cache 128 is incorporated into the processing device(s) 120. However, it will be understood that the L2 cache 128 can be integrated into the SiP device 110 separate from the processing device(s) 120. Purely by way of example, the processing device(s) 120 can be carried by a base substrate (e.g., the silicon interposer 112, a package substrate carrying the silicon interposer 112, another suitable organic substrate, an inorganic substrate, and/or any other suitable material) adjacent to the L2 cache 128 and in communication with the L2 cache 128 via one or more signal lines (or other suitable signal route lines) therein. The L2 cache 128 may be shared by one or more of the processing devices 120 (and the processing unit 122 therein). During operation of the SiP device 110, the processing unit 122 can use the registers 124 and the L1 cache 126 to complete processing operations, and attempt to retrieve data from the larger L2 cache 128 whenever a cache miss occurs in the L1 cache 126. As a result, the multiple levels of cache can help accelerate the average time it takes for the processing device(s) 120 to access data, thereby accelerating the overall processing rates.

As further illustrated in FIG. 1, the L2 cache 128 is communicatively coupled to the HBM device(s) 130 through a second communication channel 154. As illustrated, the processing device(s) 120 and HBM device(s) 130 are carried by and electrically coupled (e.g., integrated) by the silicon interposer 112. The second communication channel 154 is provided by the silicon interposer 112 (e.g., the silicon interposer includes and routes the interface signals forming the second communication channel, such as through one or more redistribution layers (RDLs)). As additionally illustrated in FIG. 1, the L2 cache 128 is also communicatively coupled to a storage device 140 through a third communication channel 156. As illustrated, the storage device 140 is outside of the SiP device 110 and utilizes signal routing components that are not contained within the silicon interposer 112 (e.g., between a packaged SiP device 110 and packaged storage device 140). For example, the third communication channel 156 may be a peripheral bus used to connect components on a motherboard or PCB, such as a Peripheral Component Interconnect Express (PCIe) bus. As a result, during the operation of the SiP device 110, the processing device(s) 120 can read data from and/or write data to the HBM device(s) 130 and/or the storage device 140, through the L2 cache 128.

In the illustrated environment 100, the HBM devices 130 include an interface die 132 and one or more stacked memory dies 134 (e.g., DRAM dies, one illustrated schematically in FIG. 1) coupled to the second communication channel 154. As explained above, the HBM device(s) 130 can be located on the silicon interposer 112, on which the processing device(s) 120 are also located. As a result, the second communication channel 154 can provide a high bandwidth (e.g., on the order of 1000 GB/s) channel through the silicon interposer 112. Further, as explained above, each HBM device 130 can provide a high bandwidth channel (not shown) between interface die 132 and/or the memory dies 134 therein. As a result, data can be communicated between the processing device(s) 120 and the HBM device(s) 130 (and components thereof) at high speeds, which can be advantageous for data-intensive processing operations. Purely by way of example, the interface die 132 can be a logic die that receives various read/write requests from the processing device(s) 120, reads/writes to the memory dies 134 in response to the requests, performs any necessary processing, and responds to the processing device(s) 120. During each read/write operation, the SiP device 110 uses a high bandwidth communication channel, allowing the read/write requests to be communicated and responded to on the order of milliseconds (e.g., in real-time). Although the HBM device(s) 130 of the SiP device 110 provide relatively high bandwidth communication, as described above, the integration of large amounts of memory and/or processing devices on the silicon interposer 112 is associated with various shortcomings.

For example, increasing the number of the memory dies 134 included in the HBM device(s) 130 can increase the memory capacity available via high bandwidth communication paths on the SiP device 110. However, as the number of the memory dies 134 increases, the signal routing and/or processing functions of the interface die 132 also increase, thereby increasing the amount of heat generated within the HBM device 130. Further, the increase in the number of the memory dies 134 positions the interface die 132 farther from temperature-controlling features external to the HBM device 130 and/or thermally insulates the interface die 132 within the HBM device 130. As a result, the temperature in the HBM device 130 can increase, thereby causing deleterious effects in the interface die 132 and/or the memory dies 134.

HBM devices, and associated systems and methods, that address the shortcomings discussed above are disclosed herein. For example, the HBM devices can include a first die (e.g., an interface die), a plurality of second dies (e.g., memory dies) carried by an active signal routing region of the first die, and one or more active through substrate vias (TSVs) positioned within a footprint of the active signal routing region. The active TSVs extend from a first metallization layer in the first die to a second metallization layer in an uppermost memory die. The HBM devices also include a cooling network configured to transport heat away from the first die. For example, the cooling network can include a thermally conductive layer carried by a thermal region of the first die and one or more cooling TSVs in contact with the thermally conductive layer of the first die. The thermally conductive TSVs extend from the thermally conductive layer of the first die to an elevation at or above an upper surface of a second die (e.g., the uppermost memory die). The thermally conductive layer (sometimes also referred to herein as a “cooling layer”) can transport heat longitudinally across a top surface of the first die toward contact points with the thermally conductive TSVs (sometimes also referred to herein as “cooling TSVs”), which then transport the heat in an upward direction away from the first die. As a result, the thermally conductive layer allows the cooling network to transport heat away from a relatively large surface area of the first die (e.g., as compared to a cooling network that only includes thermal TSVs).

In some embodiments, the cooling network also includes a cooling element carried by the upper surface of the uppermost memory die. For example, the cooling network can include a second thermally conductive layer formed on the upper surface of the uppermost memory die and/or an additional die carried by the upper surface of the uppermost memory die with a second cooling layer formed thereon. The second cooling layer can disperse heat from the thermal TSVs in a longitudinal direction over the uppermost memory die and/or additional die and increases the surface area from which heat can be carried away from the HBM device (e.g., by airflow, another cooling system, and/or the like). As a result, the second cooling layer can further increase the efficacy of the cooling network.

Additional details on the systems and methods for thermal dissipation in vertically-stacked memory devices, such as HBM devices, are set out below. For ease of reference, semiconductor systems (and their components) are sometimes described herein with reference to front and back, top and bottom, upper and lower, upwards and downwards, and/or horizontal plane, x-y plane, vertical, or z-direction relative to the spatial orientation of the embodiments shown in the figures. It is to be understood, however, that the semiconductor systems (and their components) can be moved to, and used in, different spatial orientations without changing the structure and/or function of the disclosed embodiments of the present technology.

Further, although the semiconductor systems disclosed herein are primarily discussed in the context of thermal dissipation in an HBM device, one of skill in the art will understand that the scope of the technology is not so limited. For example, the systems and methods disclosed herein can also be deployed to dissipate heat in various other stacked semiconductor settings, such as various other components of a SiP, other stacks of semiconductor dies, and the like.

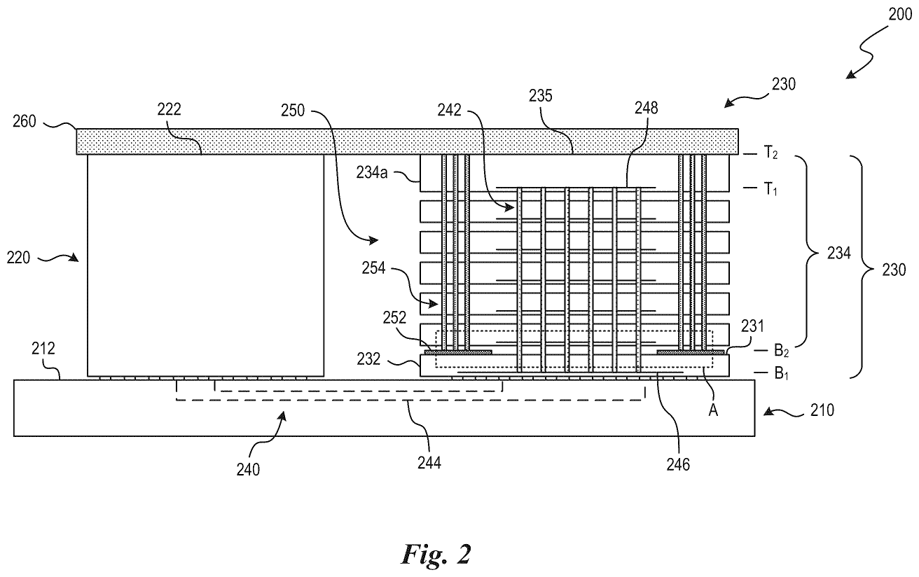

FIG. 2 is a partially schematic cross-sectional diagram of a SiP device 200 configured in accordance with some embodiments of the present technology. As illustrated in FIG. 2, the SiP device 200 can include a base substrate 210 (e.g., a silicon interposer, another organic interposer, an inorganic interposer, and/or any other suitable base substrate), as well as a processing device 220 and an HBM device 230 each integrated with an upper surface 212 of the base substrate 210. In the illustrated embodiments, the processing device 220, and associated components (e.g., the processing unit (e.g., CPU/GPU), registers, L1 cache, and the like) are illustrated as a single package, and the HBM device 230 includes a stack of semiconductor dies. The stack of semiconductor dies in the HBM device 230 includes an interface die 232 and one or more memory dies 234 (six illustrated in FIG. 2). The processing device 220 is coupled to the HBM device 230 through a high bandwidth bus 240 that includes one or more route lines 244 (two illustrated schematically in FIG. 2) formed into (or on) the base substrate 210. In various embodiments, the route lines 244 can include one or more metallization layers formed in one or more RDL layers of the base substrate 210 and/or one or more vias interconnecting the metallization layers. Further, the high bandwidth bus 240 can also include a plurality of active through substrate vias 242 (“active TSVs 242”) extending from a first base B₁ at a metallization layer 246 in the interface die 232 to a first top T₁ at a metallization layer 248 in an uppermost memory die 234a. The active TSVs 242 (sometimes also referred to herein as “signal TSVs,” “HBM bus lines,” and/or the like) allow each of the dies in the HBM device 230 to communicate data (e.g., between the memory dies 234 (e.g., DRAM dies) and the interface die 232) at a relatively high rate (e.g., on the order of 1000 GB/s or greater). Additionally, as illustrated schematically in FIG. 2, it will be understood that the processing device 220 and the HBM device 230 can each be coupled to the route lines 244 via solder structures (e.g., solder balls), metal-metal bonds, and/or any other suitable conductive bonds. As a result, components of the HBM device 230 and the processing device 220 can communicate data at the relatively high rate.

During operation of the SiP device 200, the interface die 232 generates heat (e.g., while responding to read/write requests from the processing device 220 and/or while implementing various suitable processing operations). Further, because the interface die 232 is a lowermost die in the HBM device 230, the interface die 232 can be partially insulated by the memory dies 234 such that the generated heat does not quickly dissipate through the HBM device 230. If not addressed, the heat can cause various deleterious effects in the interface die 232 and/or within the memory dies 234 that can lead to lost data, slower processing, missed reads, and/or a complete failure of one or more signal route lines in the bandwidth bus 240. To help reduce (or minimize) these deleterious effects, the HBM device 230 can include a cooling network 250 within the HBM device 230 and/or a cooling system 260 carried by an upper surface 222 of the processing device 220 and an upper surface 235 of the uppermost memory die 234a in the HBM device 230.

The cooling network 250 is configured to disperse heat away from the interface die 232 and/or memory dies 234, and towards an upper surface 235 of the uppermost memory die 234a. For example, in the illustrated embodiment, the cooling network 250 includes a cooling layer 252 thermally coupled to a top surface 231 of the interface die 232 and one or more cooling TSVs 254 (six illustrated in FIG. 2) thermally coupled to the cooling layer 252. As illustrated in FIG. 2, the cooling layer 252 (sometimes also referred to herein as a “thermally conductive layer,” a “conductive layer,” a “thermal dissipation layer,” and/or the like) is thermally coupled to a region of the top surface 231 of the interface die 232 surrounding the active TSVs 242 (sometimes referred to herein as a “thermal region”). As a result, the cooling layer 252 is positioned to dissipate heat from various circuit components in the interface die 232 in a longitudinal direction, thereby transporting the heat to contact points with the cooling TSVs 254.

The cooling TSVs 254 (sometimes also referred to herein as “thermal dissipation TSVs,” “passive TSVs,” and/or the like) extend from a second base B₂ at the cooling layer 252 (sometimes also referred to herein as a proximal region) to a second top T₂ that is at (or above) the upper surface 235 of the uppermost memory die 234a (sometimes also referred to herein as a distal region). Accordingly, the cooling TSVs 254 can dissipate the heat from the cooling layer 252 in an upward direction away from the interface die 232 (and toward the upper surface 235 of the uppermost memory die 234a).

Further, in the illustrated embodiment, the cooling TSVs 254 are thermally coupled to the cooling system 260 at (or above) the upper surface 235 of the uppermost memory die 234a. As a result, the cooling system 260 can absorb heat transported by the cooling TSVs 254, dissipate the heat in a longitudinal direction, and/or radiate the heat away from the SiP device 200. In some embodiments, the cooling system 260 includes a metal plate that can be positioned in the flow path of one or more fans. As a result, the cooling system 260 can radiate heat into the air surrounding the SiP device 200 that is then carried away by airflow from the fans.

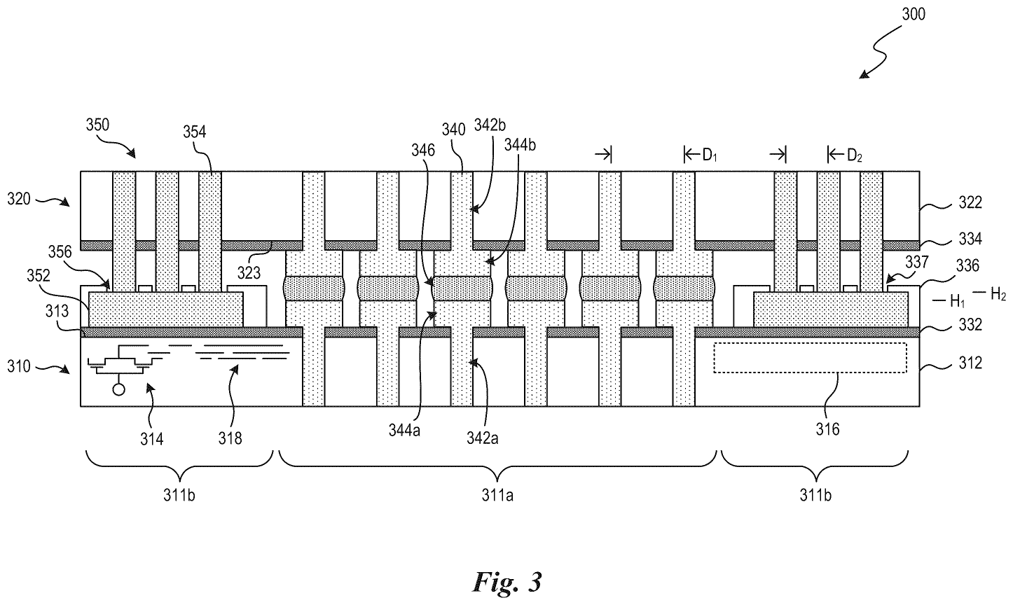

FIG. 3 is a partially schematic cross-sectional diagram of a portion of an HBM device 300 configured in accordance with some embodiments of the present technology. The portion of the HBM device 300 illustrated in FIG. 3 can correspond to a region A of the HBM device 230 illustrated in FIG. 2 such that FIG. 3 illustrates additional details that one of skill in the art will appreciate can be included in the HBM memory device 230 of FIG. 2 and/or any of the other HBM memory devices discussed herein.

For example, in the portion illustrated in FIG. 3, the HBM device 300 includes an interface die 310 and a memory die 320 (e.g., a lowermost memory die in a stack of memory dies). The interface die 310 includes a die substrate 312, as well as an active signal routing region 311a and an active circuit region 311b. In the illustrated embodiment, the active signal routing region 311a (sometimes also referred to herein as a “signal region”) is positioned in a central portion of the interface die 310 while the active circuit region 311b (sometimes also referred to herein as a “thermal signal routing region” and/or a “thermal region”) peripherally surrounds the active signal routing region 311a. A first dielectric layer 332 is formed over a top surface 313 of the die substrate 312, thereby electrically insulating the top surface 313 and/or various components of the interface die 310. Similarly, the memory die 320 includes a die substrate 322 with a lower surface 323 facing the top surface 313, as well as a second dielectric layer 334 formed over the lower surface 323.

The HBM device 300 also includes a plurality of signal TSVs 340 (six illustrated in FIG. 3, one labeled). Each of the signal TSVs includes a first segment 342a formed in the interface die 310 and a second segment 342b formed in the memory die 320. The first segment 342a is coupled to (and/or formed integrally with) a first bond pad 344a and the second segment 342b is coupled to (and/or formed integrally with) a second bond pad 344b. Further, the first bond pad 344a is coupled to the second bond pad 344b, thereby forming an individual one of the signal TSVs 340. In the illustrated embodiment, the first and second bond pads 344a, 344b are coupled by a solder structure 346 (e.g., a solder ball, solder pillar, and/or the like) therebetween. The solder structures 346 can provide a reliable conductive bond and/or help self-align the interface and memory dies 310, 320 during a stacking process. However, it will be understood that various other bonding techniques can couple the first and second bond pads 344a, 344b together. For example, the first and second bond pads 344a, 344b can be coupled by another suitable conductive element, a metal-metal bond (sometimes also referred to as a “direct bond”), and/or the like. Further, it will be understood that the signal TSVs 340 each can include a similar configuration at each die interface in the HBM device 300 (e.g., between each of the memory dies 234 of FIG. 2), thereby establishing signal communication paths through each die in the HBM device 300.

As further illustrated in FIG. 3, the interface die 310 can also include one or more circuits 314 (e.g., CMOS circuits, buffer circuitry, test circuitry, and/or the like), various other active components 316 (illustrated schematically), and one or more metallization layers 318, each formed in the active circuit region 311b. The circuits 314 and/or the other active components 316 can implement functionality for the interface die 310 while the metallization layers 318 form signal route lines within the interface die 310. For example, the metallization layers 318 can interconnect various suitable ones of the circuits 314 and/or the other active components 316. Additionally, or alternatively, the metallization layers 318 can connect the circuits 314 and/or the other active components 316 to the signal TSVs 340 to help route signals in the HBM device 300.

During operation of the HBM device 300, the circuits 314 and the other active components 316 generate heat. To help avoid deleterious effects from overheating, the HBM device 300 can also include a cooling network 350 configured to transport heat away from the interface die 310. For example, in the illustrated embodiment, the cooling network 350 includes a cooling layer 352 and a plurality of cooling TSVs 354 (six illustrated in FIG. 3) that are thermally coupled to the cooling layer 352 at contact points 356. The cooling layer 352 is formed on the first dielectric layer 332 over the active circuit region 311b (e.g., at least partially vertically aligned with the circuits 314, the other active components 316, and/or the metallization layers 318). The first dielectric layer 332 electrically insulates the cooling layer from the circuits 314, the other active components 316, and the metallization layers 318 while allowing the cooling layer 352 to absorb heat from the interface die 310. As a result, the cooling layer 352 can help dissipate heat in a lateral direction toward the contact points 356. The cooling TSVs 354 are formed in the memory die 320 (and any number of additional memory dies, as illustrated in each of the memory dies 234 of FIG. 2). Because the cooling TSVs 354 are thermally coupled to the cooling layer 352 at the contact points 356, the cooling TSVs 354 can absorb heat from the cooling layer 352 and dissipate heat vertically away from the interface die 310.

In the embodiment illustrated in FIG. 3, the cooling TSVs 354 are thermally coupled to the cooling layer 352 through direct contact with the cooling layer 352, without a bonding material and/or a metal-metal bond. The direct contact can be sufficient since the cooling TSVs 354 are not used to communicate signals in the HBM device 300 and are not bonded to specific structures. However, it will be understood that the cooling TSVs can be thermally coupled to the cooling layer 352 through various solder structures, other conductive materials (e.g., a thermal paste), metal-metal bonds, and/or any other suitable bond. In some embodiments, for example, the process of forming a metal-metal bond for the signal TSVs 340 also forms a metal-metal bond between the cooling TSVs 354 and the cooling layer 352.

As discussed above, the combination of the cooling layer 352 and the cooling TSVs 354 can improve thermal dissipation away from the interface die 310 (e.g., as compared to an HBM device that relies on radiant dissipation through the memory dies and/or active signal TSVs) by transporting heat from a relatively large surface area in the active circuit region 311b toward direct thermal pathways through the HBM device 300. In turn, the improved thermal dissipation can offset an increased distance between the interface die 310 and ambient air and/or an additional temperature generation associated with the inclusion of additional memory dies and/or a denser array of circuits in the interface die 310. As a result, the improved thermal dissipation can help allow larger and/or denser HBM devices to be constructed while reducing (or eliminating) the deleterious effects of heat.

FIG. 3 also illustrates additional details on various features of the cooling network 350. For example, in the illustrated embodiment, the HBM device 300 also includes a third dielectric layer 336 formed over the cooling layer 352 to help protect the cooling layer 352. The third dielectric layer 336 can help protect the cooling layer 352 to extend the lifespan of the cooling layer 352 (and therefore the lifetime of the HBM device 300). However, the third dielectric layer 336 can include a plurality of openings 337 to allow the cooling TSVs 354 to make direct contact with the cooling layer 352.

In another example, as further illustrated in FIG. 3, because the cooling layer 352 and the cooling TSVs 354 do not require a bond material, the cooling layer 352 can have a different thickness as compared to the first and second bond pads 344a, 344b. As a result, for example, the first bond pad 344a can extend to a first height H₁ above the top surface 313 of the interface die 310 while the cooling layer 352 can extend to a second height H₂ that is different from the first height H₁. In the illustrated embodiment, the cooling layer 352 is thicker than any of the first bond pads 344a. As a result, the second height H₂ is greater than the first height H₁. The additional thickness can increase the amount of heat the cooling layer 352 can communicate in the lateral direction. However, in some embodiments, the cooling layer 352 is thinner than any of the first bond pads 344a, which can lower the material costs to form the cooling network 350.

In yet another example, because the cooling layer 352 and the cooling TSVs 354 do not form signal routing lines, there is no signaling-related concern with shorting the cooling TSVs 354 to each other. As a result, as further illustrated in FIG. 3, the cooling TSVs 354 can have a smaller pitch than the signal TSVs 340. For example, the signal TSVs 340 are each separated by at least a first distance D₁ while the cooling TSVs 354 are separated by at least a second distance D₂ that is smaller than the first distance D₁. The first distance D₁ is large enough to avoid (or reduce the number of) electrical shorts formed between the signal TSVs 340 (e.g., by solder squeeze out, surface diffusion while forming and/or bonding the first and second bond pads 344a, 344b, and/or the like). The second distance D₂, in contrast, can be small enough that shorts would likely (or could) form between the signal TSVs 340 if they were formed at that pitch. The smaller pitch of the cooling TSVs 354 can allow a relatively large number of the cooling TSVs 354 to be formed in the available space. In turn, the smaller pitch can increase (or maximize) the conductive metal available to conduct heat away from the interface die 310, thereby increasing (or maximizing) the thermal dissipation capability of the cooling network 350.

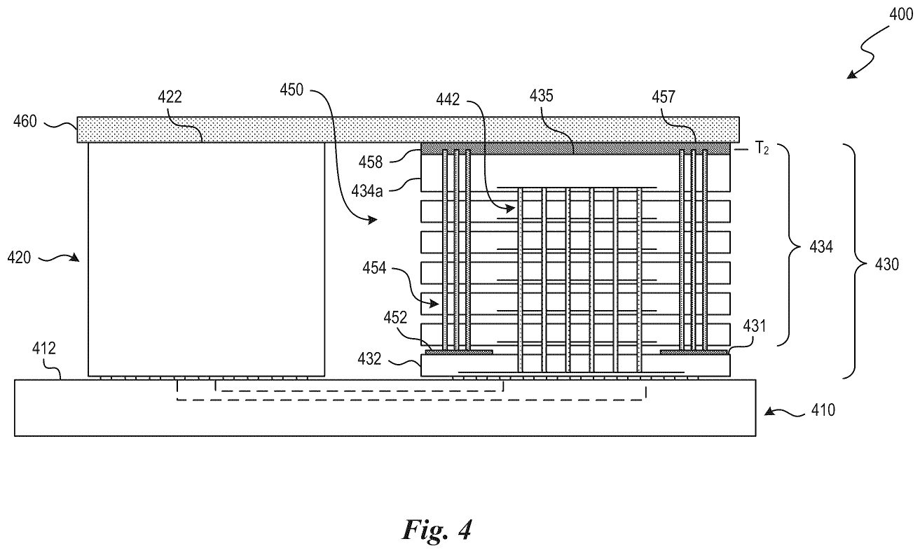

FIG. 4 is a partially schematic cross-sectional diagram of a SiP device 400 configured in accordance with further embodiments of the present technology. As illustrated in FIG. 4, the SiP device 400 is generally similar to the SiP device 200 discussed above with reference to FIG. 2. For example, the SiP device 400 of FIG. 4 includes a base substrate 410, as well as a processing device 420 and an HBM device 430 each integrated with an upper surface 412 of the base substrate 410. The HBM device 430 includes an interface die 432, one or more memory dies 434 (six illustrated in FIG. 4), a plurality of active TSVs 442 extending from the interface die 432 to an uppermost memory die 434a, and a cooling network 450 configured to transport heat away from the interface die 432.

In the illustrated embodiment, the cooling network 450 includes a first cooling layer 452 carried by a top surface 431 of the interface die 432, and one or more cooling TSVs 454 (six illustrated in FIG. 4), similar to the cooling network 250 discussed above with reference to FIG. 2. Additionally, in the illustrated embodiment, the cooling network 450 includes a second cooling layer 458 carried by an upper surface 435 of the uppermost memory die 434a. As discussed above, the first cooling layer 452 can transport heat from the interface die 432 in a longitudinal direction, thereby helping transport heat from the interface die 432 toward the cooling TSVs 454. The cooling TSVs 454 extend from the first cooling layer 452, through each of the memory dies 434, to the second elevation T₂ that is coplanar with (or above) the upper surface 435 of the uppermost memory die 434a. Accordingly, the cooling TSVs 454 can transport the heat in the first cooling layer 452 in an upward direction through the HBM device 430, then communicate the heat into the second cooling layer 458. Similar to the first cooling layer 452, the second cooling layer 458 can then dissipate heat from the cooling TSVs 454 in a longitudinal direction over the upper surface 435. As a result, the second cooling layer 458 can increase the surface area that communicates heat from the HBM device 430 to a cooling system 460 carried by an upper surface 422 of the processing device 420 and an uppermost surface 457 of the second cooling layer 458. In turn, the increase in surface area can increase the amount of heat communicated into the cooling system 460, thereby the cooling network 450 to increase (or maximize) the amount of heat dissipated from the interface die 432.

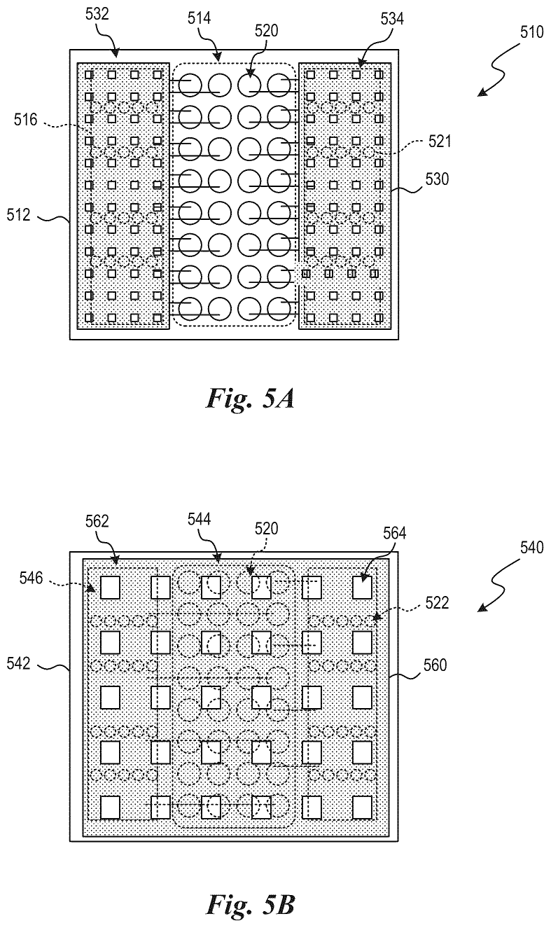

FIG. 5A is a partially schematic top view of an interface die 510 for a high-bandwidth memory device configured in accordance with some embodiments of the present technology. In the illustrated embodiment, the interface die 510 is generally similar to the interface dies 232, 432 discussed above with reference to FIGS. 2 and 4. For example, the interface die 510 includes a die substrate 512 that has a signal routing region 514 and thermal regions 516 positioned on opposing sides of the signal routing region 514. A plurality of signal TSVs 520 are formed within a footprint of the signal routing region 514 and can couple the interface die 510 to other dies in the HBM device. And a plurality of circuits and other active elements (e.g., similar to the circuits 314 and other active components 316 of FIG. 3) are formed in the thermal regions 516. As discussed above, the plurality of circuits and other active elements generate heat in the thermal regions 516 during operation of the HBM device. The heat can then be dissipated by first cooling layers 530 that are carried by, and thermally coupled to, the thermal regions 516 of the die substrate 512.

As further illustrated in FIG. 5A, the first cooling layers 530 can be formed with a mesh pattern 532 that includes a plurality of openings 534. The mesh pattern 532 can help direct heat from the interface die 510 toward contact points 521 for cooling TSVs (e.g., the contact points 356 of FIG. 3) by creating designated channels for the heat to flow in. For example, as illustrated in FIG. 5A, the cooling contact points 521 are aligned with solid portions of the first cooling layers 530 (e.g., not over openings in the mesh pattern 532). As a result, the solid portions of the mesh pattern 532 can direct heat toward the contact points 521 where the cooling TSVs to make contact with, and thermally couple to, the first cooling layers 530. Additionally, the plurality of openings 534 can provide space for air to flow through the first cooling layers 530, and over the interface die 510, which can help cool the interface die 510 without dissipating heat through a cooling network. As a result, the load on the cooling network can be reduced. Additionally, or alternatively, the mesh pattern 532 can reduce the amount of metal used in the first cooling layers 530, thereby reducing the manufacturing costs associated with forming the first cooling layers 530.

Similar to FIG. 5A, FIG. 5B is a partially schematic top view of an uppermost memory die 540 for a high-bandwidth memory device configured in accordance with some embodiments of the present technology. In the illustrated embodiment, the uppermost memory die 540 includes a dic substrate 542 that has a signal routing region 544 and memory-cell regions 546. The plurality of signal TSVs 520 are positioned within a footprint of the signal routing region 544 and can couple the uppermost memory die 540 to other dies in the HBM device (e.g., to the interface die 510 of FIG. 5A). In turn, the signal TSVs 520 are coupled to memory cells (e.g., DRAM cells, NAND flash memory cells, and/or any other suitable memory cells) in the memory-cell regions 546. Further, the uppermost memory die 540 includes a plurality of cooling TSVs 522 positioned within a footprint of the memory-cell regions 546. The cooling TSVs 522 extend through the HBM device to thermally couple the first cooling layers 530 of FIG. 5A (e.g., at the contact points 521 of FIG. 5A) to a second cooling layer 560 carried by the uppermost memory die 540.

Similar to the first cooling layers 530 discussed above, the second cooling layer 560 can be formed with a mesh pattern 562 that includes a plurality of openings 564. The mesh pattern 562 can increase the surface area of the second cooling layer 560, thereby increasing the amount of heat that can be emitted by the second cooling layer 560 away from the HBM device. Additionally, the plurality of openings 534 can provide space for air to flow through the second cooling layer 560 which can help carry heat away from the HBM device.

It will be understood that although the first cooling layers 530 and the second cooling layer 560 have been discussed and illustrated herein as having particular mesh patterns, the first and second cooling layers 530, 560 can be formed in various other patterns. Non-limiting examples of other suitable shapes include various other mesh patterns (e.g., with bigger openings, smaller openings, more openings, different grids, non-rectangular openings, and/or the like), solid layers, independent columns, independent rows, plated fins, and/or the like.

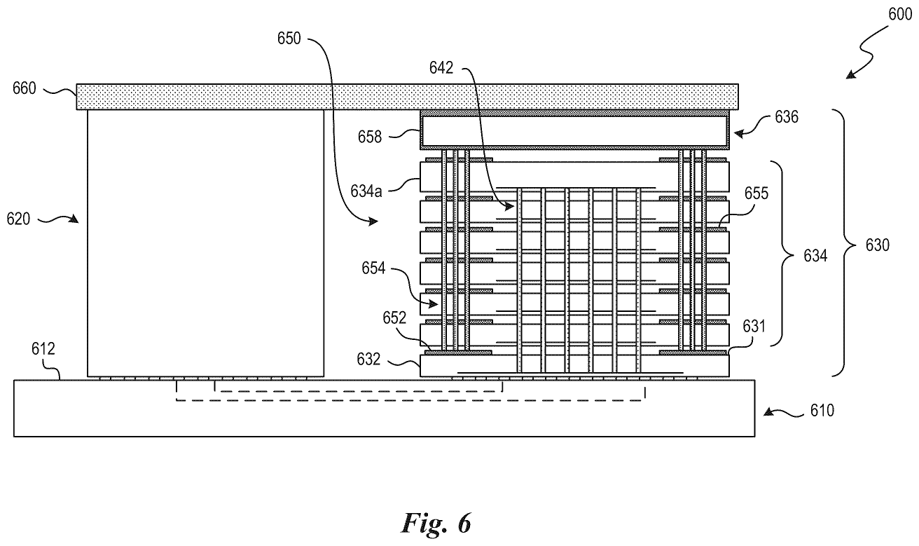

FIG. 6 is a partially schematic cross-sectional diagram of a SiP device 600 configured in accordance with further embodiments of the present technology. As illustrated in FIG. 6, the SiP device 400 is generally similar to the SiP devices 200, 400 discussed above with reference to FIGS. 2 and 4. For example, the SiP device 600 of FIG. 6 includes a base substrate 610, as well as a processing device 620 and an HBM device 630 each integrated with an upper surface 612 of the base substrate 610. The HBM device 630 includes an interface die 632, one or more memory dies 634 (six illustrated in FIG. 6), a plurality of active TSVs 642 extending from the interface die 632 to an uppermost memory die 634a, and a cooling network 650 configured to transport heat away from the interface die 632.

In the illustrated embodiment, however, the HBM device 630 further includes an additional die 636 carried by the uppermost memory die 634a. Further, the cooling network 650 can include a first cooling layer 652 carried by a top surface 631 of the interface die 632, one or more cooling TSVs 654 (six illustrated in FIG. 6), a second cooling layer 658 carried by the additional die 636, and one or more third cooling layers 655 each carried by one of the memory dies 634.

The first cooling layer 652 can transport heat from the interface die 632 in a longitudinal direction toward the cooling TSVs 654. Similarly, the third cooling layers 655 can transport heat from the memory die 634 they are carried by in a longitudinal direction toward the cooling TSVs 654. The cooling TSVs 654, in turn, extend from the first cooling layer 652, through each of the memory dies 634, to the additional die 636, allowing the cooling TSVs 654 to transport the heat from the first and third cooling layers 652, 655 in an upward direction through the HBM device 630. As a result, the cooling network 650 of FIG. 6 can also help transport heat away from electronics (e.g., memory cells) in the memory dies 634, thereby lowering the operating temperature of the memory dies 634. In turn, the reduction in the operating temperature can improve operation of the HBM device 630 (e.g., by requiring lower refresh rates in the memory dies 634).

The second cooling layer 658 is wrapped at least partially around the additional die 636. As a result, similar to the discussion above, the second cooling layer 658 can dissipate heat from the cooling TSVs 654 around the additional die 636 and in a longitudinal direction, then communicate heat into a cooling system 660. The additional die 636 can be a non-electrically functional die that provides a large amount of surface area to receive and dissipate heat into. As a result, the additional die 636 can provide a low-cost addition to the HBM device 630 that improves the functionality of the cooling network 650. Additionally, or alternatively, the additional die can be used to match an overall height of the HBM device 630 to the overall height of the processing device 620.

It will be understood that although the cooling network 650 is illustrated as including a third cooling layer 655 on each of the memory dies 634 in FIG. 6, the technology disclosed herein is not so limited. Rather, the cooling network 650 can include a third cooling layer 655 on any suitable subset of the memory dies 634. In various non-limiting examples, the cooling network 650 can include a third cooling layer 655 on only a lowermost memory die 634b, the two lowermost memory dies, the lower half of memory dies, the uppermost memory die 634a, the upper half of memory dies, every other memory dic, and/or any other suitable subset of memory dies. Further, it will be understood that although the third cooling layers 655 have been discussed in the context of the embodiments of the cooling network 650 illustrated in FIG. 6, the third cooling layer(s) 655 can be included in any of the other embodiments discussed herein. For example, the cooling network 250 of FIG. 2 can additionally include one or more third cooling layers to help dissipate heat away from the memory dies 234. Still further, it will be understood that, in some embodiments, a cooling network 650 of the type illustrated in FIG. 6 can omit the third cooling layers 655 altogether while including the additional die 636 and the second cooling layer 658.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally”, “approximately,” and “about” are used herein to mean within at least 10 percent of a given value or limit. Purely by way of example, an approximate ratio means within ten percent of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Thus, computer-readable media can comprise computer-readable storage media (e.g., “non-transitory” media) and computer-readable transmission media.

It will also be appreciated that various modifications may be made without deviating from the disclosure or the technology. For example, the dies in the HBM device can be arranged in any other suitable order (e.g., with the interface die positioned above one or more of the memory dies). Further, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. For example, the cooling network can incorporate the additional die discussed above with reference to FIG. 6 without including a third cooling layer on any of the memory dies. In another example, the cooling network can include one or more cooling layers on any subset of the memory dies (e.g., on only the lowermost memory die, the lowermost two memory dies, every other memory die, and the like) without including a cooling layer formed over the uppermost memory die.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A high-bandwidth memory (HBM) device, comprising:
a first die with an upper surface, a signal routing region, and a thermal region;
a plurality of second dies carried by the upper surface of the first die, the plurality of second dies including an uppermost die;
one or more active through substrate vias (TSVs) positioned within a footprint of the signal routing region and extending from a first metallization layer in the first die to a second metallization layer in the uppermost die; and
a cooling network configured to transport heat away from the first die, the cooling network comprising:
a thermally conductive layer carried by the upper surface of the first die over the thermal region; and
one or more cooling TSVs in contact with the thermally conductive layer and extending from the thermally conductive layer to an elevation at or above a top surface of the uppermost die.

2. The HBM device of claim 1 wherein the thermally conductive layer is a first thermally conductive layer, wherein the cooling network further comprises a second thermally conductive layer carried by the top surface of the uppermost die, and wherein the second thermally conductive layer is in contact with each of the one or more cooling TSVs.

3. The HBM device of claim 1 wherein the elevation is a first elevation, and wherein the one or more active TSVs extend to a second elevation beneath the first elevation.

4. The HBM device of claim 1 wherein the cooling network further comprises a third die carried by the uppermost die, and wherein the elevation is at or above an uppermost surface of the third die.

5. The HBM device of claim 4 wherein the thermally conductive layer is a first thermally conductive layer, wherein the third die is at least partially wrapped in a second thermally conductive layer, and wherein the second thermally conductive layer is in contact with each of the one or more cooling TSVs.

6. The HBM device of claim 1 wherein the first die includes a dielectric layer electrically insulating the thermal region of the upper surface, and wherein the thermally conductive layer is in contact with the dielectric layer.

7. The HBM device of claim 1, further comprising a dielectric layer formed over at least a portion of the thermally conductive layer, wherein the dielectric layer includes one or more openings corresponding to each of the one or more cooling TSVs to allow the one or more cooling TSVs to contact the thermally conductive layer through the dielectric layer.

8. A system-in-package (SiP) device, comprising:
an interposer substrate;
a processing unit carried by the interposer substrate; and
a high-bandwidth memory (HBM) device carried by the interposer substrate, wherein the HBM device is coupled to the processing unit by an interposer bus, and wherein the HBM device comprises:
an interface die carried by the interposer substrate;
a plurality of memory dies carried by the interface die;
a plurality of first through substrate vias (TSVs) communicably coupling each of the plurality of memory dies and the interface die; and
a cooling network configured to transport heat away from the interface die, wherein the cooling network comprises:
a conductive layer thermally coupled to and carried by an upper surface of the interface die; and
a plurality of second TSVs thermally coupled to the conductive layer and extending from the conductive layer to an elevation at or above a top surface of an uppermost memory die.

9. The SiP device of claim 8 wherein the conductive layer is a first conductive layer, and wherein the cooling network further comprises a second conductive layer carried by the top surface of the uppermost memory die and thermally coupled to the plurality of second TSVs.

10. The SiP device of claim 8 wherein the cooling network further comprises a thermal dissipation die carried by the uppermost memory die, and wherein the plurality of second TSVs extend through the thermal dissipation die.

11. The SiP device of claim 8 wherein a top surface of the processing unit is level with a top surface of the HBM device, wherein the SiP device further comprises a cooling media carried by the top surface of the processing unit and the top surface of the HBM device, and wherein the cooling media is thermally coupled to the cooling network in the HBM device.

12. The SiP device of claim 8 wherein the conductive layer is vertically aligned with one or more active circuits in the interface die.

13. The SiP device of claim 8 wherein the plurality of first TSVs have a first pitch, and wherein the plurality of second TSVs have a second pitch smaller than the first pitch.

14. The SiP device of claim 8 wherein each of the plurality of first TSVs comprises a first TSV segment formed in the interface die and a second TSV segment formed in a lowermost memory die, wherein the first TSV segment is electrically coupled to the second TSV segment via a solder structure.

15. The SiP device of claim 14 wherein a top surface of the first TSV segment is at a different elevation than a top surface of the conductive layer.

16. The SiP device of claim 8 wherein the conductive layer is formed in a mesh pattern over the upper surface of the interface die.

17. A stacked semiconductor device, comprising:
an interface die having an active signal routing region and an active circuit region;
a plurality of memory dies carried by an upper surface of the interface die, wherein each of the plurality of memory dies is communicably coupled to the interface die by a plurality of signal through substrate vias (TSVs) extending from a first metallization layer in the active signal routing region of the interface die to a second metallization layer in an uppermost memory die;
a cooling layer carried by the upper surface of the interface die over at least a portion of the active circuit region; and
a plurality of cooling TSVs each having a proximal region thermally coupled to the cooling layer at a contact point and a distal region at an elevation parallel to or above a top surface of the uppermost memory die, wherein:
the cooling layer is configured to communicate heat in a lateral direction towards the contact points, and
the plurality of cooling TSVs are configured to communicate heat in an upward direction away from the cooling layer.

18. The stacked semiconductor device of claim 17 wherein the proximal region of each of the plurality of cooling TSVs is in direct contact with the cooling layer at the contact point.

19. The stacked semiconductor device of claim 17 wherein the cooling layer is a first cooling layer, and wherein the stacked semiconductor device further comprises a second cooling layer carried by an upper surface of a lowermost memory die, wherein the cooling TSVs extend through and are thermally coupled to the second cooling layer.

20. The stacked semiconductor device of claim 17 wherein the cooling layer is a first cooling layer, and wherein the stacked semiconductor device further comprises a second cooling layer thermally coupled to the distal region of each of the plurality of cooling TSVs.
